(19) United States
(12) Patent Application Publication
(10) Pub. No.: US 2012/0024317 A1
(43) Pub. Date: Feb. 2, 2012

(54) CLEANING APPARATUS AND CLEANING METHOD

(75) Inventors: Yoshinori KITAMURA, Mie (JP); Yasuhito Yoshimizu, Kanagawa (JP); Koichiro Shibayama, Mie (JP)

(73) Assignee: Kabushiki Kaisha Toshiba, Tokyo (JP)

(21) Appl. No.: 13/191,739

(22) Filed: Jul. 27, 2011

(30) Foreign Application Priority Data
Jul. 27, 2010 (JP) 2010-168442

(51) Int. Cl. B08B 7/04; H01L 21/02; B08B 3/00

(52) U.S. Cl. 134/6; 134/137; 134/56 R; 134/157

(57) ABSTRACT

According to one embodiment, a cleaning apparatus includes a removing unit whose tip portion is harder than a constituent material of a surface layer on a back surface side of a semiconductor wafer (wafer) and which is configured to clean a back surface of the wafer held by a holding unit and a moving mechanism that relatively moves the removing unit and the wafer in a direction parallel to the wafer back surface. The removing unit grinds and removes a protrusion that is formed of a material same as the surface layer of the wafer back surface, by the moving mechanism relatively moving the removing unit and the wafer and causing the tip portion of the removing unit to come into contact with the protrusion.

### CROSS-REFERENCE TO RELATED APPLICATION

This application is based upon and claims the benefit of priority from Japanese Patent Application No. 2010-168442, filed on Jul. 27, 2010; the entire contents of which are incorporated herein by reference.

### FIELD

Embodiments described herein relate generally to a cleaning apparatus and a cleaning method.

### BACKGROUND

Conventionally, a photolithography is used in a manufacturing process of semiconductor devices. In the dimensional accuracy of a resist pattern formed on a wafer in the photolithography, an exposure amount, an exposure focus position (focus position), and the like at the time of exposure are important factors. Therefore, it is needed to realize an accurate focus position for forming a resist pattern as designed.

However, when foreign matter, dust, or the like is adhered to the back surface of a wafer at the time of exposure, the position of a light receiving surface is displaced from a focus position in an optical axis direction, i.e., defocusing occurs, so that a resist pattern is not formed as designed. For removing foreign matter or the like adhered to the surface of a wafer, a cleaning apparatus is used that removes foreign matter or the like on the surface of a wafer by using a brush. However, it is usually not performed to remove protrusions present on the back surface of a wafer.

The Chemical Mechanical Polishing (CMP) process is performed to planarize the whole surface of a wafer by grinding the whole surface. However, the CMP process uses abrasive such as slurry, so that the configuration of an apparatus and the process become complicated.

Therefore, in the cleaning apparatus and the cleaning method, a technology for efficiently removing protrusions present on the back surface of a wafer is desired.

### BRIEF DESCRIPTION OF THE DRAWINGS

FIG. 1 is a diagram schematically illustrating a configuration of a cleaning apparatus according to a first embodiment;

FIG. 2A to FIG. 2C are cross-sectional views schematically explaining a cleaning method of the back surface of a wafer by the cleaning apparatus according to the first embodiment;

FIG. 3A to FIG. 3C are cross-sectional views schematically explaining a cleaning method of the back surface of another wafer by the cleaning apparatus according to the first embodiment;

FIG. 4 is a conceptual diagram explaining a case of performing a cleaning process by a brush while maintaining a constant pressure with respect to minor warpage of a wafer in the cleaning apparatus; and

FIG. 5A to FIG. 5D are cross-sectional views schematically explaining a cleaning method of the back surface of a wafer according to a second embodiment.

### DETAILED DESCRIPTION

In general, according to one embodiment, a cleaning apparatus includes a holding unit capable of holding a semiconductor wafer, a removing unit whose tip portion is harder than a constituent material of a surface layer on a back surface side of the semiconductor wafer and which is configured to clean a semiconductor-wafer back surface to be a process target surface of the semiconductor wafer held by the holding unit, and a moving mechanism that relatively moves the removing unit and the semiconductor wafer in a direction parallel to the semiconductor-wafer back surface. The removing unit grinds and removes a protrusion that is formed of a material same as the surface layer of the semiconductor-wafer back surface, by the moving mechanism relatively moving the removing unit and the semiconductor wafer in the direction parallel to the semiconductor-wafer back surface and causing the tip portion of the removing unit to come into contact with the protrusion.

The embodiments of a cleaning apparatus will be explained below in detail based on the drawings. In the drawings illustrated below, the scale of each member is different from a realistic one in some cases for easy understanding. The same thing can be said between the drawings.

### First Embodiment

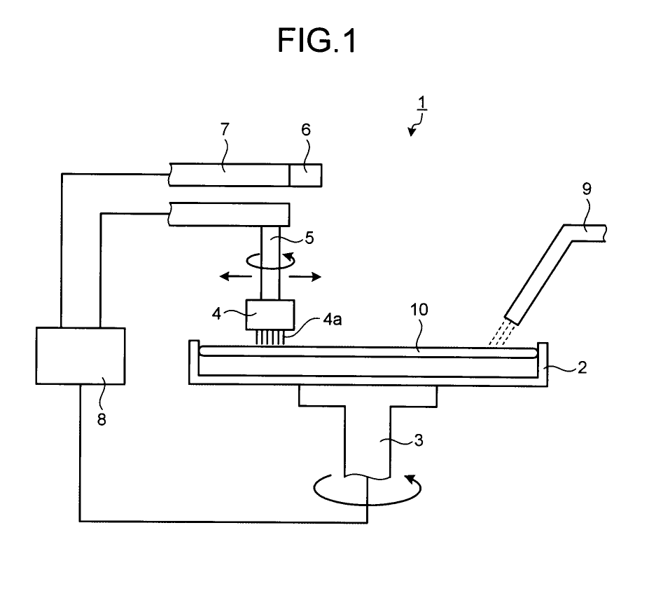

FIG. 1 is a diagram schematically illustrating a configuration of a cleaning apparatus 1 according to the first embodiment. As shown in FIG. 1, the cleaning apparatus 1 according to the present embodiment includes a wafer holding unit 2, a wafer rotation driving unit 3, a brush 4, a brush driving unit 5, a sensor unit 6, a sensor driving unit 7, a control unit 8, and a cleaning-water supplying unit 9.

The wafer holding unit 2 can hold a semiconductor wafer 10 (hereinafter, wafer 10), which is a process target substrate, by gripping the periphery of the wafer 10 with the back surface facing upward. The back surface is a surface on the opposite side of the surface of the wafer 10 on which a semiconductor device is formed. The wafer holding unit 2 grips the periphery of the side surface of the wafer 10 by a wafer gripping unit (not shown) at least at two positions.

The wafer rotation driving unit 3 horizontally rotates the wafer holding unit 2 holding the wafer 10 at a given rotation speed in a circumferential direction with the center of the wafer 10 in a plane direction as an axis. The rotation speed of the wafer 10 is appropriately set depending on the condition such as a material of a protrusion on the back surface of the wafer 10 to be a removing target and a material of brush bristles 4a. As will be described later, the sensor unit 6 provides length measurement information to the control unit 8 that controls elevation of the brush 4 to keep the distance from the back surface of the wafer 10 approximately constant. At this time, the rotation speed of the wafer 10 can be set to the rotation speed at which length measurement of the sensor unit 6 and control of the control unit 8 follow the rotation of the wafer 10 and does not necessarily need to be high speed.

In the brush 4 as a removing unit of foreign matter and protrusions on the wafer 10, a plurality of the brush bristles 4a is supported and arranged to have, for example, a columnar shape on the surface of its main body facing the wafer 10. The arrangement of the brush bristles 4a is not limited to the above-described columnar shape and various forms can be employed, such as a form in which the brush bristles 4a are arranged to have a ring shape on the surface facing the wafer 10 and a form in which the brush bristles 4a are arranged to have a line shape on the surface facing the wafer 10. The tip portions of the brush bristles 4a are formed of a material whose hardness is higher than the constituent material of the back surface of the wafer 10. Moreover, the brush bristles 4a formed of a plurality of materials can be used.

The constituent material of the back surface of the wafer 10, for example, includes a silicon film, a carbon film, an organic material film, a silicon oxide film, and a silicon nitride film. For surely removing protrusions formed of these films, the hardness of the brush bristle 4a is preferably 30 degrees or more. Moreover, a superhard brush with diamond chips can be used. The hardness in this example is a measured value by a type A durometer according to JIS K 6253 (Rubber. vulcanized or thermoplastic-Determination of hardness) or JIS K 7215 (Testing Methods for Durometer Hardness of Plastics). Moreover, when this hardness is 90 degrees or higher, the hardness can be measured by a type D durometer of the same standard.

Moreover, when the outermost-layer film of the back surface of the wafer 10 is thin, a lower-layer film under the outermost-layer film of the back surface of the wafer 10 may be present in a protrusion. In this case, it is possible to appropriately select the hardness of the brush bristles 4a, for example, for the harder material between the material of the outermost-layer film and the material of the lower-layer film thereunder of the back surface of the wafer 10.

Furthermore, in this example, the brush 4 is illustrated as the removing unit of foreign matter and protrusions on the wafer 10, however, a deburring cutter for the back surface of the wafer 10 can be used other than the brush 4. In the cutter, for example, a plurality of cutter blades is arranged on the surface facing the wafer 10 to have a shape such as a columnar shape, a ring shape, and a line shape. The tip portions of the cutter blades, which are in contact with foreign matter and protrusions on the wafer 10, are formed of a material whose hardness is higher than the constituent material of the back surface of the wafer 10. The brush bristle 4a, although hard, has some flexibility in the tip portion thereof. Therefore, the brush 4 has a responsiveness to warpage of the back surface of the wafer 10 higher than a cutter blade.

The brush driving unit 5 raises and lowers the brush 4 to a given height above the wafer 10 held by the wafer holding unit 2. Moreover, the brush driving unit 5 rotates the brush 4 at a given rotation speed and moves the brush 4 in a predetermined direction over the surface of the wafer 10 held by the wafer holding unit 2. The brush driving unit 5 can move the brush 4, for example, in a radial direction of the wafer 10 while horizontally rotating the blush 4.

The sensor unit 6 is composed of a length measurement sensor capable of measuring the distance to the wafer 10, for example, by instantly calculating the time for light such as laser to be reflected from the wafer 10. The sensor unit 6 can be raised and lowered above the wafer 10 in the height direction by being driven by the sensor driving unit 7 and can move also in a given direction in the plane direction of the wafer 10.

The control unit 8 performs control of the wafer rotation driving unit 3, the brush driving unit 5, the sensor unit 6, and the sensor driving unit 7. The cleaning-water supplying unit 9 supplies, for example, cleaning water as cleaning liquid onto the wafer 10 during the cleaning process or after the cleaning process and washes out grinding swarf generated in the cleaning process from the back surface of the wafer 10.

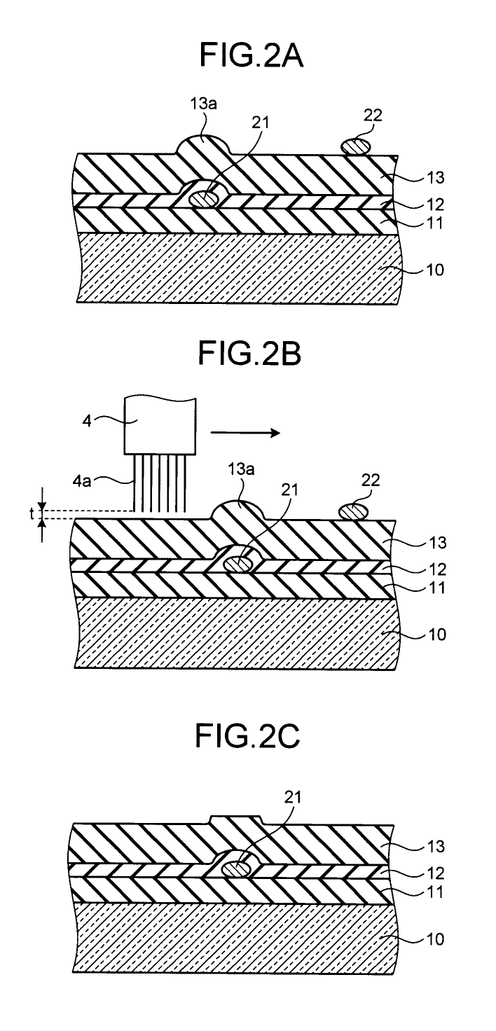

Next, the cleaning process by the cleaning apparatus 1 is explained with reference to FIG. 2A to FIG. 2C. FIG. 2A to FIG. 2C are cross-sectional views schematically explaining the cleaning method of the back surface of the wafer 10 by the cleaning apparatus 1 according to the first embodiment.

First, the wafer 10, which is a process target substrate, is held by the wafer holding unit 2 so that the back surface faces upward. As shown in FIG. 2A, a first coating 11, a second coating 12, and a third coating 13, which are formed in respective processes for manufacturing a semiconductor device to be formed on the surface of the wafer 10, are stacked in this order on the back surface of the wafer 10. This wafer 10 is a wafer in a state before exposure, in which a photoresist film is formed on the semiconductor device surface. The cleaning process by the cleaning apparatus 1 can be performed on the wafer 10 in a state in which a photoresist film is not formed yet on the semiconductor device surface. Moreover, the cleaning process by the cleaning apparatus 1 can be performed in the process using a stacked resist. In this case, for example, after forming a lower-layer resist on the semiconductor device surface of the wafer 10, the cleaning process by the cleaning apparatus 1 is performed on the back surface of the wafer 10. Next, the wafer 10 is introduced into an exposure apparatus and exposure is performed after forming an upper-layer resist on the lower-layer resist in the exposure apparatus.

A foreign matter 21 is adhered to part of the first coating 11 of the back surface of the wafer 10. The region over the foreign matter 21 in the second coating 12 and the third coating 13 has a shape conforming to the shape of the foreign matter 21. Therefore, on the third coating 13 that is the outermost layer of the back surface of the wafer 10, a protrusion 13a is formed in the region over the foreign matter 21. In other words, the protrusion 13a is a protrusion formed of a material same as the third coating 13 that is the surface layer of the back surface of the wafer 10. In FIG. 2A, one protrusion 13a is focused on, however, a plurality of other protrusions similar to the protrusion 13a is present on the surface of the third coating 13. Moreover, a foreign matter 22, which is formed of a material different from the third coating 13, and debris (not shown), which scatters, for example, when the back surface of the wafer 10 is damaged and is formed of a material same as the third coating 13, are also adhered to the third coating 13. In this example, foreign matter that is formed on the back surface without being processed or removed through a plurality of manufacturing processes in this manner is called an accumulated foreign matter.

Next, the brush 4 is arranged in the center portion of the back surface of the wafer 10 by the brush driving unit 5. The brush 4 is arranged in a state of floating by a constant separation distance t from the flat surface of the third coating 13 at the height at which the tip portions of the brush bristles 4a can come into contact with the protrusion 13a. Specifically, the brush 4 is arranged to be separated from the flat surface of the third coating 13 at the height at which the position of the tip portions of the brush bristles 4a is lower than the height of the protrusion 13a and the tip portions is not in contact with the flat surface of the third coating 13. The brush 4 is rotated by being driven by the brush driving unit 5.

Next, the wafer rotation driving unit 3 horizontally rotates the wafer holding unit 2, so that the wafer 10 held by the wafer holding unit 2 rotates. The rotation speed of the wafer 10 and the rotation speed of the brush 4 can be appropriately changed depending on the conditions such as the material of the surface layer of the back surface of the wafer 10 and the material of the brush bristles 4a. Next, as shown in FIG. 2B, the brush 4 horizontally moves in the radial direction of the wafer 10 along with driving of the wafer rotation driving unit 3 in a state of being separated from the flat surface of the third coating 13 by approximately the constant separation distance t. Specifically, the brush 4 is arranged in the center portion of the back surface of the wafer 10 and is horizontally moved toward the periphery therefrom while rotating by the brush driving unit 5. Then, the brush 4 reciprocates over the wafer 10 a plurality of times in the radial direction of the wafer 10.

In this manner, the brush 4 horizontally moves relative to the rotating wafer 10, so that the brush bristles 4a of the brush 4 come into contact with the protrusion 13a. Consequently, the protrusion 13a is ground by the brush 4 and is removed in a state of leaving a portion with the height corresponding to the distance between the brush bristles 4a and the flat surface of the third coating 13, i.e., the thickness corresponding to the separation distance t, as shown in FIG. 2C. Moreover, the foreign matter 22 adhered to the surface of the third coating 13 is ground or stripped by the brush bristles 4a of the brush 4 coming into contact therewith, thereby being removed from the surface of the third coating 13. The grinding means to physically remove foreign matter and protrusions on the back surface of the wafer 10 by the brush bristles 4a as a grinding unit and includes concepts of polishing and cutting. At this time, cleaning water is supplied onto the wafer 10 from the cleaning-water supplying unit 9, whereby grinding swarf generated in the cleaning process can be washed out from the back surface of the wafer 10. Grinding swarf can be removed also by blowing air to the wafer 10. Moreover, grinding swarf can be removed from the back surface of the wafer 10 by suctioning it.

Next, control of the separation distance t when warpage occurs in the wafer 10 is explained. First, the brush 4 is arranged at the position sufficiently separated from the back surface of the wafer 10 over the wafer 10 by the brush driving unit 5.

Next, the sensor unit 6 measures the distance from the sensor unit 6 to the brush 4 and the distance from the sensor unit 6 to the back surface of the wafer 10 (the third coating 13). The sensor unit 6 measures the distance from the sensor unit 6 to the brush 4 and the distance from the sensor unit 6 to the back surface of the wafer 10 (the third coating 13) in the peripheral region of the brush 4, for example, in a vertical direction. The sensor unit 6 is movable in synchronization with the brush 4 by the control unit 8 controlling the sensor driving unit 7 and can perform measurement in accordance with the movement of the brush 4. Then, the sensor unit 6 sends these length measurement information to the control unit 8.

The control unit 8 stores information on the length from the measurement reference position of the brush 4 (position of the main body of the brush 4) to the tips of the brush bristles 4a, for example, in a storing unit included in the control unit 8. The control unit 8 calculates the distance from the tips of the brush bristles 4a to the flat surface of the back surface of the wafer 10 based on this information and the length measurement information sent from the sensor unit 6. The sensor unit 6 and the control unit 8 configure a detecting unit that detects the distance from the tip portions of the brush bristles 4a to the flat surface of the back surface of the wafer 10. Then, the control unit 8 controls the height of the brush 4 so that this distance becomes appropriately the constant separation distance t excluding a portion over the protrusion 13a of the wafer 10 when performing the cleaning process by moving the brush 4 in the plane direction of the wafer 10. Consequently, the cleaning process can be performed while reflecting the warped state of the wafer 10.

The rotation speed of the wafer 10 in the case of controlling while monitoring change in the separation distance t due to the warped state of the wafer 10 in this manner is desirably a lower rotation speed. This is effective, especially, when the tendency of the warpage is uniform from the center to the periphery in the plane of the wafer 10. Moreover, the rotation speed of the wafer 10 can be increased after obtaining information on the tendency of warpage of the wafer 10 by the sensor unit 6 and the control unit 8.

Moreover, in terms of the distance to the back surface of the wafer 10 (the third coating 13) measured by the sensor unit 6, it is possible to distinguish between change in distance due to the protrusion 13a in the third coating 13 and change in distance due to warpage of the wafer 10, for example, as follows. For example, change in distance is measured at a plurality of points around the brush 4 and the average thereof or the like is calculated to distinguish between the changes. For example, when the distance to the back surface of the wafer 10 (the third coating 13) is shorter than the average value by a predetermined distance or more, it is determined that change in distance is due to the protrusion 13a. Moreover, when the distance to the back surface of the wafer 10 (the third coating 13) is longer than the average value by a predetermined range, it is determined that change in distance is due to warpage of the wafer 10.

The measurement by the sensor unit 6 described above can be performed while performing the cleaning process. Moreover, it is possible to perform the measurement by the sensor unit 6 described above in advance and store the information on warpage of the back surface of the wafer 10 in the storing unit of the control unit 8 before performing the cleaning process. In this case, the control unit 8 can control the distance from the tips of the brush bristles 4a to the back surface of the wafer 10 while reflecting the state of warpage of the wafer 10 by using the information on warpage of the wafer 10 stored in the storing unit. It is possible that a function unit related to control of the separation distance t, such as the sensor unit 6, the sensor driving unit 7, and the storing unit, is an apparatus separated from the cleaning apparatus 1.

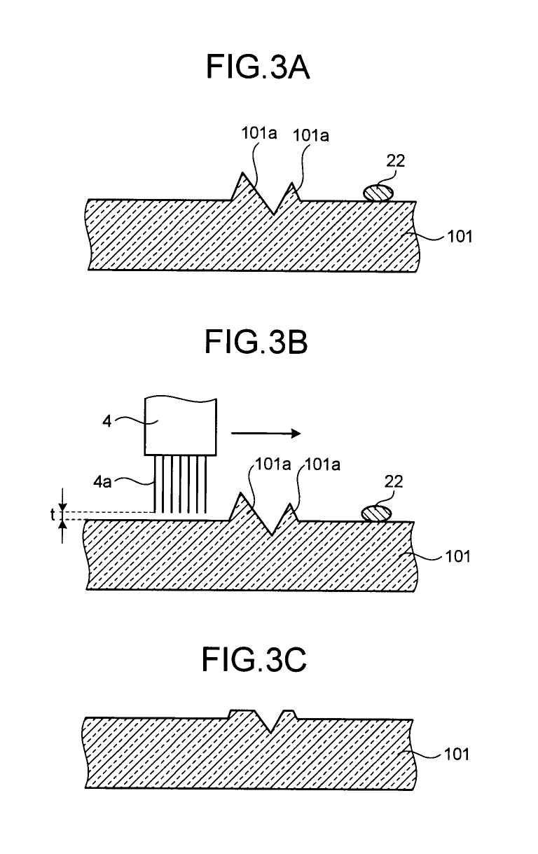

FIG. 3A to FIG. 3C are cross-sectional views schematically explaining the cleaning method of the back surface of another wafer 101 by the cleaning apparatus 1 according to the first embodiment. This wafer 101 is a wafer in a state before exposure, in which a photoresist film is formed on the device surface. The cleaning process by the cleaning apparatus 1 can be performed on a wafer in a state in which a photoresist film is not formed yet on the semiconductor device surface.

As shown in FIG. 3A, the back surface of the wafer 101 itself is damaged, so that protrusions 101a are formed on the back surface of the wafer 101. In other words, the protrusion 101a is a protrusion formed of a material same as the back surface of the wafer 101. The foreign matter 22 formed of a material different from the back surface of the wafer 101 is adhered to the back surface of the wafer 101.

In the similar manner to the case of the cleaning process on the back surface of the wafer 10 described above, the cleaning process is performed on the wafer 101. In this case again, as shown in FIG. 3B, the brush bristles 4a come into contact with the protrusions 101a by relatively moving the brush 4 and the wafer 101. Consequently, the protrusions 101a are ground by the brush 4 and are removed while leaving a portion with the height corresponding the distance between the brush bristles 4a and the flat surface of the back surface of the wafer 101, i.e., the thickness corresponding to the separation distance t, as shown in FIG. 3C. Moreover, the foreign matter 22 adhered to the back surface of the wafer 101 is ground or stripped by the brush bristles 4a coming into contact therewith, whereby the foreign matter 22 is removed.

In the manufacturing process of semiconductor devices, the photolithography process is performed, for example, to form a patterned film on a wafer. The photolithography process is largely classified into a photoresist-film forming process of applying a photosensitive film on a film, which is deposited on a wafer and is to be patterned, an exposure process of exposing a pattern on the photoresist film, and a developing process of removing part of the photoresist film by developing the exposed photoresist film and thereby forming a resist pattern. In such a photolithography process, in order to form a resist pattern accurately as designed, especially, in the exposure process, it is necessary to project a mask pattern with no blur on a photoresist film. In other words, it is needed to realize an accurate focus position as designed.

Even if foreign matter on the surface side is removed at the time of exposure, when a protrusion due to the accumulated foreign matter formed on the back surface of a wafer or due to damage, such as scratch, on the back surface of a wafer is present, the height of the wafer deviates from a desired set height due to this protrusion. Therefore, the position of a light receiving surface is displaced from the focus position in the optical axis direction, i.e., defocusing occurs. When the defocusing occurs, a resist pattern as designed is not formed, so that another photolithography process (rework) is needed. Performing the rework results in decreasing the production efficiency. Moreover, the photolithography process uses an exposure apparatus, which is expensive, and therefore is a high-cost process. Thus, performing the rework results in increasing the production cost.

As described above, foreign matter adhered to the surface of a wafer among protrusions present on the wafer can be removed by a conventionally-used cleaning apparatus using a brush. However, on the other hand, there is a protrusion formed of a material same as a surface layer of the back surface as shown in FIG. 2A and FIG. 3A on the back surface of the wafer. Such a protrusion is generated, for example, when the surface layer of the back surface of a wafer is damaged or when a coating is formed on the back surface of a wafer which is damaged or to which foreign matter is adhered. Moreover, when a plurality of coatings is stacked on the back surface of a wafer and a coating in the middle is damaged or foreign matter is adhered thereto, such a protrusion is generated. The protrusion, which is formed of a material same as a surface layer on the back surface side of a wafer and is formed on the back surface of a wafer in this manner, cannot be removed by the conventional cleaning apparatus that removes foreign matter by a brush.

However, in the cleaning apparatus 1 in the present embodiment, it is possible to grind and remove a protrusion that is formed of a material same as a surface layer of the back surface of a wafer and is formed on the back surface of the wafer. Moreover, in the cleaning apparatus 1, foreign matter adhered to the back surface of a wafer can be also removed by grinding or stripping it from the back surface of the wafer. Consequently, planarization and cleaning of the back surface of a wafer can be realized.

The cleaning process of the back surface of a wafer by the cleaning apparatus 1 is performed, for example, on a wafer, which is a target to be subjected to the rework, before the exposure process, desirably, immediately before the exposure process. The exposure process is performed on a wafer whose back surface is subjected to the cleaning process by the cleaning apparatus 1, so that the effect of a minor protrusion on the back surface of a wafer can be reduced and whereby occurrence of another defocusing can be prevented. Moreover, the cleaning process by the cleaning apparatus 1 can be performed on all wafers every time before performing the exposure process in the photolithography process. Furthermore, the cleaning process by the cleaning apparatus 1 can be performed before forming a photoresist film or can be performed after forming a photoresist film.

In the above present embodiment, explanation is made for the case of using the brush 4 as the removing unit of foreign matter and protrusions on the back surface of the wafer 10 as an example, however, it is also possible to use, for example, a cutter in which a plurality of cutter blades is arranged to have a columnar shape on the surface facing the wafer 10 instead of the brush 4 and perform control of the separation distance t in the similar manner to the above.

In the cleaning apparatus 1 described above, the effect of minor protrusion and recess on the back surface of a wafer at the time of exposure can be reduced by selectively grinding and planarizing only a protruded portion instead of planarizing the whole surface-layer film of a wafer by polishing it as in the conventional CMP technology. Consequently, occurrence of the rework can be suppressed and decrease in the production efficiency and increase in the production cost can be prevented. The cleaning process by such a cleaning apparatus 1 is preferable, particularly, for immersion exposure in which an effect of defocusing at the time of exposure to the accuracy of a resist pattern is large.

Moreover, the cleaning apparatus 1 described above does not use abrasive such as slurry as in the CMP, so that a planarizing process can be easily performed by an apparatus with a simple configuration.

Furthermore, other than suppression of occurrence of defocusing in the photolithography process, the cleaning process of the back surface of a wafer by the cleaning apparatus 1 has an effect of preventing occurrence of a failure due to minor protrusion and recess on the back surface by performing the cleaning process before a process that is affected by the minor protrusion and recess on the back surface.

In the above, explanation is made for the case in which the cleaning process is performed in a state where the tip portions of the brush bristles 4a are separated from the flat surface of the back surface of the wafer 10 by approximately the constant separation distance t, however, the cleaning process of the back surface of the wafer 10 can be performed in a state where the separation distance t is zero, i.e., the tip portions of the brush bristles 4a are in contact with the flat portion of the back surface of the wafer 10. The sensor unit 6 and the control unit 8 perform control of setting the separation distance t to zero in the cleaning process of the back surface of the wafer 10. In this case again, a protrusion formed of a material same as the back surface of the wafer 10 and foreign matter formed of a material different from the back surface of the wafer 10 can be removed from the back surface of the wafer 10 and cleaning of the back surface of the wafer 10 can be performed.

### Second Embodiment

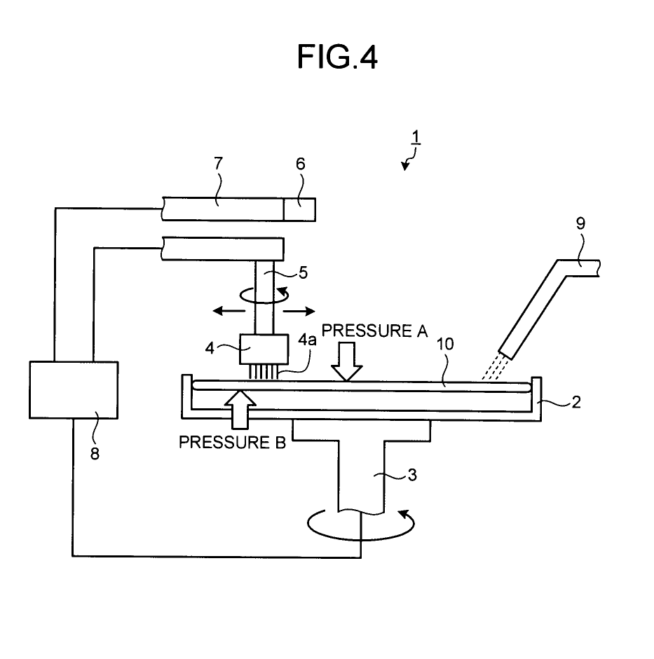

FIG. 4 is a conceptual diagram explaining a case of performing the cleaning process by the brush 4 while maintaining a constant pressure with respect to minor warpage of the wafer 10 in the cleaning apparatus 1. In this embodiment, a pressure A is applied from above the wafer 10 and a pressure B is applied from below the wafer 10, with respect to the wafer 10 in which minor warpage occurs. In other words, the pressure A is applied to the back surface of the wafer 10 and the pressure B is applied to the device surface of the wafer 10. The pressure A is a pressure applied to the brush 4 when the brush 4 comes into contact with the back surface of the wafer 10. The pressure B is a pressure applied from a not-shown pressurizing mechanism to correct minor warpage of the wafer 10. The pressurizing mechanism is provided below the wafer 10 to rotate in synchronization with the rotation of the wafer 10. The pressure B can be applied to the whole surface of the back surface of the wafer 10 or can be applied to the region facing the brush 4 via the wafer 10 during the cleaning process.

Then, the control unit 8 performs control so that the pressure A becomes equal to the pressure B, for example, by using an air spring such as an air suspension on the brush driving unit 5 side. By moving the brush 4 in a state of being in contact with the back surface of the wafer 10 while performing such control, a protrusion that is formed of a material same as a surface layer of the back surface side of the wafer 10 and is formed on the back surface of the wafer 10 can be ground and removed without measuring the separation distance t as in the case of the first embodiment. Moreover, foreign matter adhered to the back surface of the wafer 10 can be ground or stripped from the back surface of the wafer 10 to be removed. Consequently, in the similar manner to the case of the first embodiment, only the protruded portion can be selectively ground to be planarized.

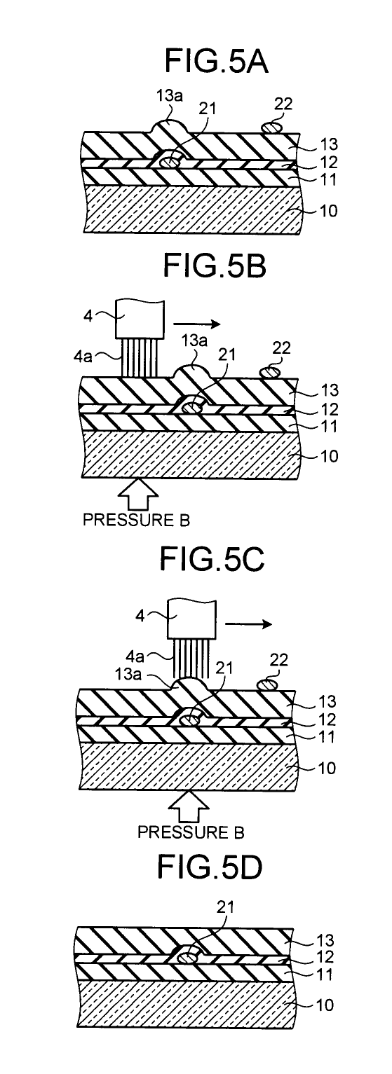

Next, the cleaning process of the back surface of a wafer according to the second embodiment is explained with reference to FIG. 5A to FIG. 5D. FIG. 5A to FIG. 5D are cross-sectional views schematically explaining the cleaning method of the back surface of a wafer according to the second embodiment. In FIG. 5A to FIG. 5D, members same as those in FIG. 2A to FIG. 2C are given the same reference numerals.

First, the wafer 10 is held by the wafer holding unit 2 so that the back surface faces upward. As shown in FIG. 5A, the first coating 11, the second coating 12, and the third coating 13, which are formed in respective processes for manufacturing a semiconductor device to be formed on the front surface of the wafer 10, are stacked in this order on the back surface of the wafer 10. On the third coating 13 present in the outermost layer of the back surface of the wafer 10, the protrusion 13a is formed and the foreign matter 22 is adhered. The wafer 10 is a wafer in a state before exposure, in which a photoresist film is formed on the semiconductor device surface.

Next, the brush 4 is arranged in the center portion of the back surface of the wafer 10 by the brush driving unit 5. The brush 4 is arranged in a state where the tip portions of the brush bristles 4a are in contact with the flat surface of the third coating 13 by the brush driving unit 5, i.e., in a state where the separation distance t is zero, to apply the pressure A to the back surface of the wafer 10. Moreover, on the device surface of the wafer 10, the predetermined pressure B (constant pressure) is applied to the region facing the brush 4 via the wafer 10 by the not-shown pressurizing mechanism. At this time, in the brush driving unit 5, the pressure A is set to the pressure same as the pressure B by using an air spring (pressure A=pressure B). Then, the brush 4 rotates by being driven by the brush driving unit 5.

Next, the wafer rotation driving unit 3 horizontally rotates the wafer holding unit 2, so that the wafer 10 held by the wafer holding unit 2 rotates. Next, as shown in FIG. 5B, the brush 4 horizontally moves in the radial direction of the wafer 10 along with driving of the wafer rotation driving unit 3 in a state of being in contact with the flat surface of the third coating 13. Moreover, on the device surface of the wafer 10, the pressure B is applied to the region facing the brush 4 by the pressurizing mechanism via the wafer 10 in accordance with the movement of the brush 4. Then, the brush 4 reciprocates on the wafer 10 a plurality of times in the radial direction of the wafer 10.

As shown in FIG. 5C, when the brush bristles 4a of the brush 4 come into contact with the protrusion 13a, the brush 4 grinds the protrusion 13a while being pressed upward and the pressure (pressure A) applied to the brush 4 increases. When the brush bristles 4a pass the protrusion 13a, the brush bristles 4a become the state of being in contact with the flat surface of the third coating 13, so that the pressure (pressure A) applied to the brush 4 decreases and the pressure A becomes equal to the pressure B. In the brush driving unit 5, it is possible to absorb the displacement of the brush 4 in a direction vertical to the back surface of the wafer 10 in synchronization with increase in pressure (pressure A) applied to the brush 4 by an elastic action of an air spring. Moreover, in the brush driving unit 5, when the brush 4 passes the protrusion 13a on the wafer 10 and comes into contact with the flat surface on the outer side of the protrusion 13a, the brush 4 can be restored to the original state from the displaced state by an elastic action of an air spring. As the height of the protrusion 13a decreases by repeating grinding of the protrusion 13a, the rising range of the pressure (pressure A) applied to the brush 4 becomes small. The same thing can be said to the case where the brush bristles 4a of the brush 4 come into contact with the foreign matter 22.

Then, when the protrusion 13a and the foreign matter 22 disappear as shown in FIG. 5D, the pressure A becomes always equal to the pressure B (constant pressure) on the back surface of the wafer 10. Specifically, by performing grinding until the pressure A becomes equal to the pressure B (constant pressure) on the whole surface of the back surface of the wafer 10, the protrusion 13a and the foreign matter 22 can be removed and thus the back surface of the wafer 10 can be planarized. Consequently, only the protruded portion on the back surface of the wafer 10 can be selectively ground to be planarized without controlling the separation distance t.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cleaning apparatus comprising:
a holding unit capable of holding a semiconductor wafer;
a removing unit whose tip portion is harder than a constituent material of a surface layer on a back surface side of the semiconductor wafer and which is configured to clean a semiconductor-wafer back surface to be a process target surface of the semiconductor wafer held by the holding unit; and
a moving mechanism that relatively moves the removing unit and the semiconductor wafer in a direction parallel to the semiconductor-wafer back surface,
wherein
the removing unit grinds and removes a protrusion that is formed of a material same as the surface layer of the semiconductor-wafer back surface, by the moving mechanism relatively moving the removing unit and the semiconductor wafer in the direction parallel to the semiconductor-wafer back surface and causing the tip portion of the removing unit to come into contact with the protrusion.

2. The cleaning apparatus according to claim 1, wherein the moving mechanism relatively moves the removing unit and the semiconductor wafer while keeping a distance between the tip portion of the removing unit and the semiconductor-wafer back surface to approximately a constant distance at which the tip portion of the removing unit is separated from the semiconductor-wafer back surface excluding the protrusion and the tip portion of the removing unit is in contact with the protrusion.

3. The cleaning apparatus according to claim 2, further comprising a detecting unit that detects the distance between the tip portion of the removing unit and the semiconductor-wafer back surface.

4. The cleaning apparatus according to claim 3, wherein the detecting unit includes a distance sensor, measures a distance from the distance sensor to the removing unit and a distance from the distance sensor to the semiconductor-wafer back surface by the distance sensor, and detects the distance between the tip portion of the removing unit and the semiconductor-wafer back surface based on a measurement result.

5. The cleaning apparatus according to claim 1, wherein the moving mechanism relatively moves the removing unit and the semiconductor wafer in a state where the removing unit is in contact with the semiconductor-wafer back surface with a predetermined pressure while enabling to absorb displacement of the removing unit in a direction vertical to the semiconductor-wafer back surface, which is caused by the protrusion, by an elastic action and restore the removing unit from a displaced state on an outer side of the protrusion.

6. The cleaning apparatus according to claim 1, further comprising a supplying unit that supplies cleaning liquid onto the semiconductor-wafer back surface.

7. The cleaning apparatus according to claim 1, further comprising a driving unit that rotates the semiconductor wafer in a circumferential direction.

8. The cleaning apparatus according to claim 7, wherein the moving mechanism rotates the removing unit in a plane direction of the semiconductor wafer above the semiconductor wafer.

9. The cleaning apparatus according to claim 1, wherein
the removing unit includes
a plurality of grinding units that grinds the protrusion by the tip portion that is harder than the constituent material of the surface layer on the back surface side of the semiconductor wafer coming into contact with the protrusion, and
a body unit that supports the grinding units.

10. The cleaning apparatus according to claim 1, wherein the removing unit is a brush.

11. A cleaning method comprising grinding and removing a protrusion that is formed of a material same as a surface layer of a semiconductor-wafer back surface, by relatively moving a removing unit whose tip portion is harder than a constituent material of the surface layer on a back surface side of the semiconductor wafer in a direction parallel to the semiconductor-wafer back surface and causing the tip portion of the removing unit to come into contact with the protrusion.

12. The cleaning method according to claim 11, wherein the removing unit and the semiconductor wafer are relatively moved while keeping a distance between the tip portion of the removing unit and the semiconductor-wafer back surface to approximately a constant distance at which the tip portion of the removing unit is separated from the semiconductor-wafer back surface excluding the protrusion and the tip portion of the removing unit is in contact with the protrusion.

13. The cleaning method according to claim 11, wherein the removing unit and the semiconductor wafer are relatively moved in a state where the removing unit is in contact with the semiconductor-wafer back surface with a predetermined pressure while enabling to absorb displacement of the removing unit in a direction vertical to the semiconductor-wafer back surface, which is caused by the protrusion, by an elastic action and restore the removing unit from a displaced state on an outer side of the protrusion.

14. The cleaning method according to claim 11, wherein the protrusion that is formed due to adhesion of a foreign matter is removed by causing the tip portion of the removing unit to come into contact with the protrusion.

15. The cleaning method according to claim 11, wherein the protrusion that is formed by the surface layer on the back surface side of the semiconductor wafer being damaged is removed by causing the tip portion of the removing unit to come into contact with the protrusion.

16. The cleaning method according to claim 11, wherein cleaning liquid that removes grinding swarf generated by grinding the protrusion is supplied onto the semiconductor-wafer back surface.

17. The cleaning method according to claim 11, wherein the semiconductor wafer is rotated in a circumferential direction and the removing unit and the semiconductor wafer are relatively moved.

18. The cleaning method according to claim 17, wherein the removing unit is rotated in a plane direction of the semiconductor wafer above the semiconductor wafer.

19. The cleaning method according to claim 11, wherein
the removing unit includes
a plurality of grinding units that grinds the protrusion by the tip portion that is harder than the constituent material of the surface layer on the back surface side of the semiconductor wafer coming into contact with the protrusion, and
a body unit that supports the grinding units.

20. The cleaning method according to claim 11, wherein the removing unit is a brush.
